(19) United States
(12) Patent Application Publication
(10) Pub. No.: US 2016/0372211 A1
(43) Pub. Date: Dec. 22, 2016

(54) ERROR DETECTION APPARATUS FOR A SEMICONDUCTOR MEMORY DEVICE

(71) Applicant: KABUSHIKI KAISHA TOSHIBA, Tokyo (JP)

(72) Inventor: Keisyun LIN, Kawasaki Kanagawa (JP)

(21) Appl. No.: 15/061,603

(22) Filed: Mar. 4, 2016

(30) Foreign Application Priority Data
Jun. 22, 2015 (JP) 2015-125088

(51) Int. Cl. G11C 29/38; G11C 29/44; G11C 7/22

(52) U.S. Cl. CPC G11C 29/38; G11C 7/222; G11C 29/44

(57) ABSTRACT

An error detection apparatus includes an address generation circuit configured to output an address designating a memory cell unit of a semiconductor memory device to be tested, the memory cell unit including a plurality of memory bits, a test data generation circuit configured to generate test data to be written to the memory cell unit, a control circuit configured to cause the test data to be written to the memory cell unit designated by the address, in synchronization with a cycle of a clock signal, and the written test data to be read from the memory cell unit, in synchronization with the next cycle of the clock signal, and a comparison circuit configured to compare the written test data and the read test data.

### CROSS-REFERENCE TO RELATED APPLICATION

This application is based upon and claims the benefit of priority from Japanese Patent Application No. 2015-125088, filed Jun. 22, 2015, the entire contents of which are incorporated herein by reference.

### FIELD

Embodiments described herein relate generally to an error detection apparatus for a semiconductor memory device.

### BACKGROUND

In a semiconductor integrated apparatus which requires high reliability of a semiconductor memory unit, particularly, a random access memory unit, a test of the semiconductor memory unit is performed as an initial diagnosis when the semiconductor integrated apparatus is powered on. Through the test, it is determined whether or not each memory bit of the semiconductor memory unit works properly.

In the related art, this type of test may be performed by a CPU of the apparatus executing software containing a test program. That is, the CPU causes data to be written to a target memory bit to be tested in the semiconductor memory unit and reads data stored in the target memory bit. A process of comparing the written data to the read data is performed for each memory bit through the test program.

For this reason, significant amount of time would be necessary to carry out the test. Further, since the CPU may not perform other processing during the test, an initial operation time of the semiconductor integrated apparatus may be increased.

### DESCRIPTION OF THE DRAWINGS

FIG. 1 is a block diagram illustrating a semiconductor integrated apparatus including a semiconductor error detection apparatus according to a first embodiment.

FIG. 2 is a block diagram illustrating the semiconductor error detection apparatus according to the first embodiment.

FIG. 3 is a block diagram illustrating a data generation circuit of the semiconductor error detection apparatus according to the first embodiment.

FIG. 4 is a timing diagram illustrating an operation of the semiconductor error detection apparatus according to the first embodiment.

FIG. 5 is a flowchart illustrating an operation of the semiconductor error detection apparatus according to the first embodiment.

FIG. 6 is a block diagram illustrating a semiconductor integrated apparatus according to a comparative example.

FIG. 7 is a flowchart illustrating another operation of the semiconductor error detection apparatus according to the first embodiment.

FIG. 8 is a block diagram illustrating a semiconductor integrated apparatus including a semiconductor error detection apparatus according to a second embodiment.

FIG. 9 is a block diagram illustrating a semiconductor error detection apparatus according to a third embodiment.

### DETAILED DESCRIPTION

One or more embodiments of the present disclosure provide a semiconductor error detection apparatus that reduces time for testing each bit in a semiconductor memory unit.

According to an embodiment, an error detection apparatus includes an address generation circuit configured to output an address designating a memory cell unit of a semiconductor memory device to be tested, the memory cell unit including a plurality of memory bits, a test data generation circuit configured to generate test data to be written to the memory cell unit, a control circuit configured to cause the test data to be written to the memory cell unit designated by the address, in synchronization with a cycle of a clock signal, and the written test data to be read from the memory cell unit, in synchronization with the next cycle of the clock signal, and a comparison circuit configured to compare the written test data and the read test data.

Hereinafter, embodiments will be described with reference to the accompanying drawings.

### First Embodiment

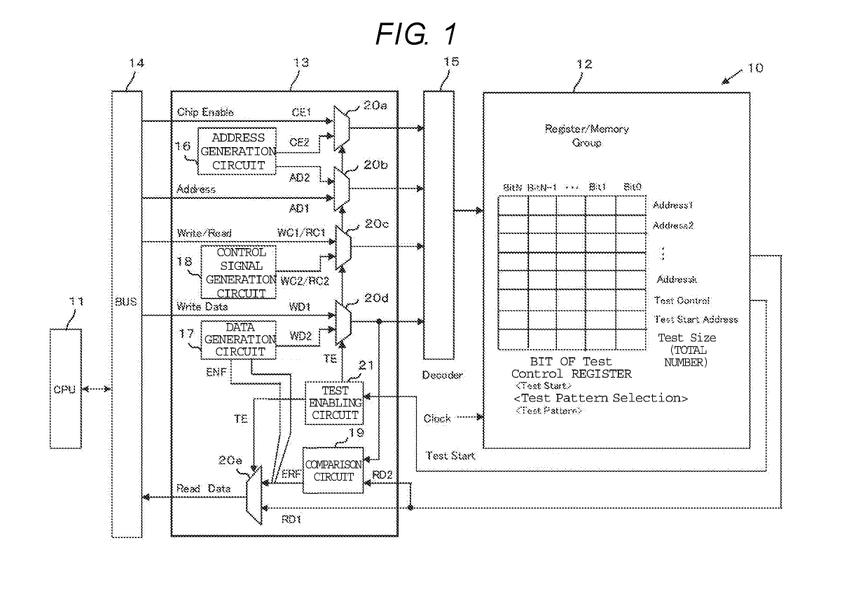

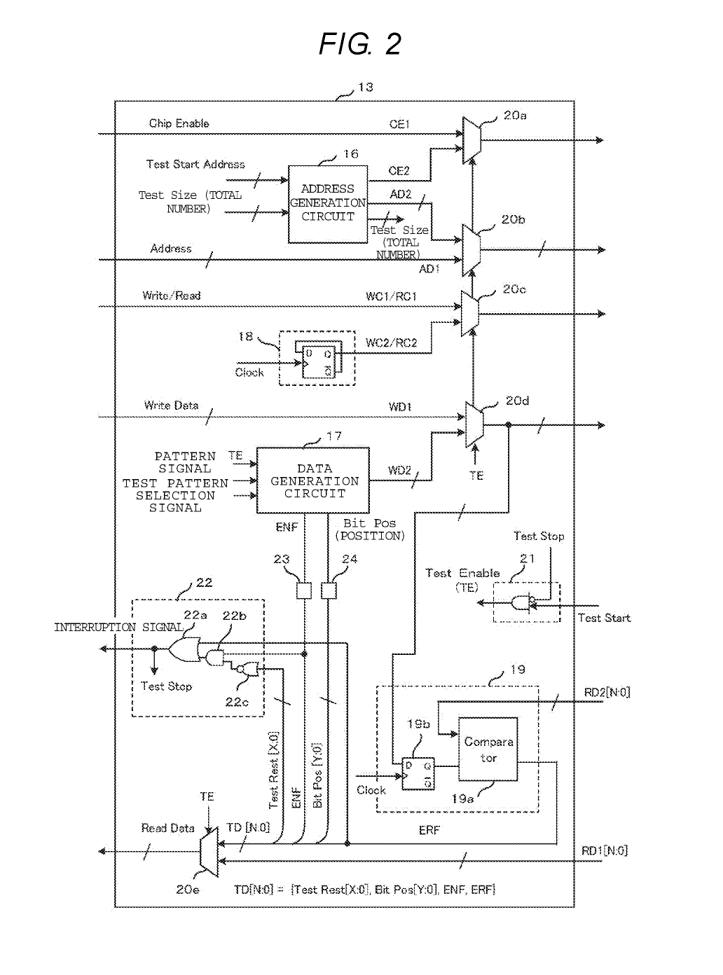

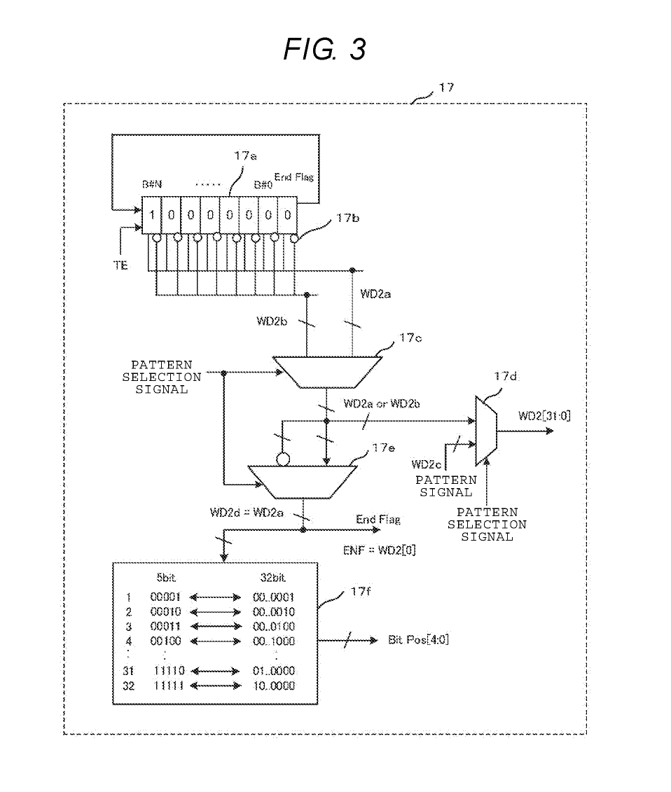

A semiconductor error detection apparatus according to a first embodiment will be described with reference to FIGS. 1 to 3. FIG. 1 is a block diagram of a semiconductor integrated apparatus including the semiconductor error detection apparatus according to the first embodiment. FIG. 2 is a block diagram of the semiconductor error detection apparatus according to the first embodiment. FIG. 3 is a detailed block diagram of a data generation circuit of the semiconductor error detection apparatus according to the first embodiment.

The semiconductor integrated apparatus including the semiconductor error detection apparatus will be described hereinafter.

As illustrated in FIGS. 1 to 3, the semiconductor integrated apparatus 10 is a system-on-chip (SOC) which includes a central processing unit (CPU) (information processing apparatus) 11 and a semiconductor memory 12. The CPU 11 performs various information processing. The semiconductor memory 12 stores various data or programs necessary for the information processing. The semiconductor integrated apparatus 10 further includes the semiconductor error detection apparatus 13 between the CPU 11 and the semiconductor memory 12.

The semiconductor error detection apparatus 13 is provided so as to perform a test of determining whether there is a defective bit in the semiconductor memory 12 for each bit when power is supplied to the semiconductor integrated apparatus 10. The semiconductor memory 12 may be a static random access memory (SRAM), for example.

The semiconductor integrated apparatus 10 performs normal processing when each bit of the semiconductor memory 12 passes the test, and transitions to a safe mode and takes remedial measures when a defective bit is detected in the semiconductor memory 12.

In the semiconductor integrated apparatus 10, the CPU 11 transmits and receives information such as data and commands to and from the semiconductor memory 12 through a bus 14. Here, software is basically implemented by the CPU 11 to control data to be read from and written in the semiconductor memory 12. Specifically, the CPU 11 causes data to be written in the semiconductor memory 12 and causes data to be read from the semiconductor memory 12 by performing processes as follows.

The CPU 11 transmits a chip enabling signal CE1 for causing the semiconductor memory 12 to be in an active state, to the semiconductor memory 12. The CPU 11 transmits, for example, an address AD1 for designating a memory cell unit on which writing is to be performed, data WD1 to be written in the designated memory cell unit, a command WC1 of writing the data, when data is written in the semiconductor memory 12.

The CPU 11 transmits, for example, an address AD1 for designating a memory cell unit on which reading is performed, and a command RC1 of reading the data, and receives data RD1 read from the designated memory cell unit, when data is read from the semiconductor memory 12.

A decoder 15 is provided so as to receive the chip enabling signal, the address, the command of writing or reading data, data to be written, and the like, and to generate a control signal for controlling an operation of the semiconductor memory 12.

In the semiconductor integrated apparatus 10, the semiconductor error detection apparatus 13 may transmit and receive data, commands, and the like from and to the semiconductor memory 12, independently from the CPU 11. The semiconductor error detection apparatus 13 performs the test of the semiconductor memory 12 for each bit with only hardware configuration.

The semiconductor error detection apparatus 13 includes an address generation circuit 16, a data generation circuit 17, a control signal generation circuit 18, a comparison circuit 19, a selection circuit 20, and a test enabling circuit 21.

The address generation circuit 16 generates an address AD2 for designating a memory cell unit in the semiconductor memory 12, which has the predetermined number of bits including a test bit. For example, the number of bits of the memory cell unit is 32-bit (one word). That is, the test bit corresponds to any bit in one word. The address generation circuit 16 generates a chip enabling signal CE2 and then generates the address AD2.

The data generation circuit 17 generates first data WD2 which includes test data to be written to the test bit and is to be written in the memory cell unit designated by the address AD2. The first data WD2 may be also described as write data WD2.

The control signal generation circuit 18 is used for instructing to write the first data WD2 in the memory cell unit designated by the address AD2 and to read second data RD2 stored in the memory cell unit designated by the address AD2 from the memory cell unit. Specifically, the control signal generation circuit 18 transmits a write command WC2 and a read command RC2 to the semiconductor memory 12. The second data RD2 may be also described as read data RD2.

The comparison circuit 19 compares the first data WD2 with the second data RD2, and then outputs a result of comparison. Specifically, the comparison circuit 19 sets an error flag ERF as a logical value of 1 when the first data WD2 and the second data RD2 do not coincide with each other.

The selection circuit 20 includes a plurality of selectors 20a to 20e. The selection circuit 20 is provided so as to select a normal operation of writing data in and reading data from the semiconductor memory 12 by the CPU 11 or the test for each bit of the semiconductor memory 12 by the semiconductor error detection apparatus 13. The selection circuit 20 is a collective term of the selectors 20a to 20e.

The selector 20a selects either of the chip enabling signal CE1 transmitted from the CPU 11 and the chip enabling signal CE2 transmitted from the address generation circuit 16, and then transmits the selected chip enabling signal to the decoder 15.

The selector 20b selects the address AD1 transmitted from the CPU 11, or the address AD2 transmitted from the address generation circuit 16, and then transmits the selected address to the decoder 15.

The selector 20c selects the write command WC1 or read command RC1 transmitted from the CPU 11, or the write command WC2 or read command RC2 transmitted from the control signal generation circuit 18, and then transmits the selected write command or read command to the decoder 15.

The selector 20d selects the write data WD1 transmitted from the CPU 11 or the write data WD2 transmitted from the data generation circuit 17, and then transmits the selected write data to the decoder 15.

The selector 20e selects the read data RD1 read from the semiconductor memory 12 or a result of the test by the semiconductor error detection apparatus 13, and then transmits the selected data to the CPU 11. Although will be described below, the result of the test by the semiconductor error detection apparatus 13 corresponds to data including the address AD2, a position of the test bit, the error flag ERF, an end flag ENF, and the like.

The selection circuit 20 causes the chip enabling signal, the address, the write/read command, and the write data to be switched between the ones transmitted by the CPU 11 or the ones transmitted by the semiconductor error detection apparatus 13.

When the selection circuit 20 selects the chip enabling signal CE1, the address AD1, the write command WC1/read command RC1, and the write data WD1 from the CPU 11, the CPU 11 performs the normal operation of writing data in and reading data from the semiconductor memory 12.

When the selection circuit 20 selects the chip enabling signal CE2, the address AD2, the write command WC2/read command RC2, and the write data WD2 from the semiconductor error detection apparatus 13, the semiconductor error detection apparatus 13 performs the test for each bit of the semiconductor memory 12.

When the test enabling circuit 21 detects a test starting signal sent from the test control register of the semiconductor memory 12 when the semiconductor integrated apparatus 10 performs an initial operation, the test enabling circuit 21 sets the test enabling signal TE as a logical value of 1.

The test enabling circuit 21 transmits the test enabling signal TE to each of the selectors 20a to 20e. As a result, the selection circuit 20 selects the chip enabling signal CE2, the address AD2, the write command WC2, and the write data WD2, which are transmitted from the semiconductor error detection apparatus 13.

When the test enabling circuit 21 detects a test stopping signal, the test enabling circuit 21 sets the test enabling signal TE as a logical value of 0. As a result, the selection circuit 20 selects the chip enabling signal CE1, the address AD1, the write command WC1, the read command RC1, and the write data RD1, which are transmitted from the CPU 11.

Various kinds of information used for performing the test for each bit are stored in advance in the semiconductor memory 12. The semiconductor memory 12 includes a register for storing test control information, a register for storing an test starting address, a register for storing a test size (total number of memory cell units on which the test for each bit is performed), for example.

For example, information on test start, selection of a test pattern, the test pattern, and the like is stored in the register for the test control information.

Next, the semiconductor error detection apparatus 13 will be described in detail.

The semiconductor error detection apparatus 13 performs synchronization with a system clock signal of the semiconductor integrated apparatus 10 and then performs the test for each bit for the semiconductor memory 12.

The address generation circuit 16 includes a register, a counter, a latch (not illustrated), and the like. The address generation circuit 16 receives the test starting address and the test size from the semiconductor memory 12 and stores the received address and test size in the register. The address generation circuit 16, in synchronization with the system clock signal, generates the address AD2 which designates a memory cell unit including the test bit in the semiconductor memory 12, and transmits the generated address AD2 to the selector 20b.

The address generation circuit 16 sets the test starting address as a default of the address AD2, and then performs increment on the address AD2 for each of two cycles of the system clock signal.

Simultaneously, the address generation circuit 16 outputs a test rest (remaining number of memory cell units on which the test for each bit is performed).

The address generation circuit 16 sets the test size as an initial value of the test rest and performs decrement on the test rest for each of the two cycles of the system clock signal.

The test rest is used for specifying a position (address AD2) of a word including a defective bit when an error occurs in performing of the test for each bit, as will be described below.

The address generation circuit 16 generates the chip enabling signal CE2 for activating the semiconductor memory 12, and transmits the generated chip enabling signal CE2 to the selector 20a.

The data generation circuit 17 includes a shift register 17a, an inversion circuit 17b, selectors 17c, 17d, and 17e, a decoder 17f, and the like in order to generate data having a specific pattern, as the first data WD2.

The shift register 17a generates data WD2a having the specific pattern. The inversion circuit 17b generates data WD2b by inverting the data WD2a. The selector 17c selects the data WD2a or the data WD2b in accordance with a pattern selection signal.

The selector 17d selects the data selected by the selector 17c or certain data WD2c in accordance with a pattern selection signal. The data selected by the selector 17d is the first data WD2.

The selector 17e is provided so as to detect the end flag ENF when the first data WD2 is the data WD2a or WD2b which has the specific pattern. Similarly, the decoder 17f is provided so as to detect a position of the test bit.

The shift register 17a may be a 32-bit shift register, for example. The end flag ENF is assigned to the least significant bit of the shift register 17a.

An initial value of the shift register 17a may be set as (100 . . . 00), that is, the most significant bit is set as a logical value of 1 and other bits are set as a logical value of 0. The logical value of 1 and the logical value of 0 are simply referred to as 1 and 0 below.

When the shift register 17a receives the test enabling signal TE, the shift register 17a sequentially shifts the logical value of each bit from an upper bit to an adjacent lower bit for each of the two cycles of the system clock. The least significant bit (end flag ENF) of the shift register 17a is shifted to the most significant bit of the shift register 17a.

Specifically, sequential shifting is performed in an order of (100 . . . 00)->(010 . . . 00)-> . . . ->(000 . . . 10)->(000 . . . 01), in the shift register 17a. When shifting (taking a round) is performed 32 times (taking a round), the end flag ENF becomes 1, and this indicates that generation of the test data corresponding to one word is ended.

That is, only the test bit, which is one of 32 bits (one word) of the data WD2a, is 1 and other bits are 0. Such test data is referred to as one hot data.

Thus, only the test bit which is one of the 32 bits (one word) is 0 and other bits are 1 in the data WD2b obtained by inverting the data WD2a. Such test data is referred to as one cool data.

One hot data representing that a state of only one bit is opposite to states of other bits is sequentially applied as an input of data to the semiconductor memory 12 with a sequential change of a bit position of the inverted data. As a result only a state of a writing of each one bit which is connected to the memory may be sequentially different from states of writing of other bits.

An error due to interference between bits adjacent to each other (even-numbered bit and odd-numbered bit) may be detected using the one hot data. The similar error may be also detected using the one cool data.

The selector 17e outputs the data WD2d equivalent to the data WD2a even when the selector 17c selects the data WD2a or the data WD2b.

Thus, when data output from the selector 17c is either the one hot data (WD2a) or the one cool data (WD2b), an initial value of the end flag ENF at the least significant bit (LSB) of the data WD2d output from the selector 17e is 0. When generation of the data WD2a corresponding to the one word is ended, the end flag ENF is set as 1.

The decoder 17f decodes the 32-bit data WD2d to be 5-bit data in order to detect the position of the test bit. When the address AD2 has 32 bits, there are 32 (fifth power of 2) cases as to the position of the test bit. Thus, the position of the test bit may be represented by 5 bits. The decoder 17f is a logic decoder which includes a logical circuit, for example.

When the address AD2 has 32 bits, the first data WD2 is represented by WD2 [31:0], the end flag ENF is represented by WD2 [0], and a position of the defective bit is represented by Bit Pos[4:0].

When the selector 17d selects the certain data WD2c in accordance with the pattern selection signal, the CPU 11 performs the following operations.

(1) The CPU 11 sets a certain test pattern as <Test Pattern>of the test control register. The certain test pattern is the data WD2c.

(2) When the error flag ERF is detected in performing of the test for each bit by using the certain test pattern, interruption occurs in the CPU 11. When an error occurs, the test stopping signal of an interruption circuit 22 is set as 1 and the test enabling signal TE of the test enabling circuit 21 is set as 0. As a result, switching from a mode of the test for each bit to the normal operation mode is automatically performed.

(3) In the normal operation mode, the CPU 11 reads data of the address at which the error occurs and compares the read data and the test pattern to each other. Based on the comparison, it is possible to confirm the position of the defective bit.

Here, the register 17a, the selectors 17c and 17e, and the decoder 17f continuously performs an operation regardless of whether the first data WD2 is the data WD2a or WD2b which has the specific pattern or the data WD2c which has the certain pattern.

The data generation circuit 17 is configured in such a manner that the data generation circuit 17 starts generation of the first data WD2 when the test enabling signal TE is 1, and the generation circuit 17 stops generation of the first data WD2 when the test enabling signal TE is 0.

The control signal generation circuit 18 includes a D-type flip-flop. The D-type flip-flop causes a value of a D input terminal to be held as an output of a Q terminal at a rising edge of a clock input to a C (Clock) terminal.

The control signal generation circuit 18 generates the write command WC2 at a rising edge in a first cycle of the system clock and generates the read command RC2 at a rising edge in a second cycle of the system clock.

The comparison circuit 19 includes a comparator 19a and a D-type flip-flop 19b. The first data WD2 generated by the data generation circuit 17 is input to a first input terminal of the comparator 19a through the D-type flip-flop 19b. The second data RD2 read from the memory cell unit in the semiconductor memory 12, which is designated by the address AD2, is input to a second input terminal of the comparator 19a.

The D-type flip-flop 19b is provided so as to adjust timings of the first data WD2 and the second data RD2. The D-type flip-flop 19b performs latching on the first data WD2 at a rising edge of the system clock.

The comparison circuit 19 compares the first data WD2 with the second data RD2. When the first data WD2 and the second data RD2 do not coincide with each other, the comparison circuit 19 sets the error flag ERF as 1.

The test enabling circuit 21 includes an AND circuit. The test starting signal is input to a first input terminal of the AND circuit and a signal obtained by inverting the test stopping signal is input to a second input terminal. The AND circuit outputs a logical product of the test starting signal and the signal input to the second input terminal as the test enabling signal TE. Since initial values of the test starting signal and the test stopping signal are 0, the test enabling signal TE is 0.

When power is supplied to the semiconductor integrated apparatus 10, if the CPU 11 sets Test Start of the test control register as 1, the test enabling signal TE becomes 1, and thereby the selection circuit 20 performs switching. Thus, the semiconductor integrated apparatus 10 is operated in the mode of the test for each bit, by the semiconductor error detection apparatus 13.

When the test for each bit is completed, the test stopping signal becomes 1 and thus the test enabling signal TE becomes 0. As a result, the selection circuit 20 performs switching and thus the semiconductor integrated apparatus 10 is operated in the normal operation mode.

The interruption circuit (notification circuit) 22 is provided so as to transmit an interruption signal to the CPU 11 when a defective bit is detected in the semiconductor memory 12 and when each bit of the semiconductor memory 12 passed the test.

The CPU 11 obtains a result of the test by the interruption signal. The CPU 11 analyzes the result of the test and thus may recognize whether the defective bit has been detected or each bit passed the test. When the defective bit has been detected, it is possible to specify an address of the memory cell unit including the detected defective bit and a position of the detected defective bit.

The interruption signal is used as the test stopping signal for resetting the test enabling signal TE and causing the semiconductor integrated apparatus 10 to return to the normal operation mode.

The interruption circuit 22 includes an OR circuit 22a, an AND circuit 22b, and a multi-input NOR circuit 22c, for example. The test rest (remaining number) is input to the multi-input NOR circuit 22c. The multi-input NOR circuit 22c outputs 0 when the test for each bit is in progress, i.e., when the test rest (remaining number) is not zero, and outputs 1 when each bit passed the test, i.e., when the test rest (remaining number) is zero.

An output of the multi-input NOR circuit 22c and the end flag ENF are input to the AND circuit 22b. The AND circuit 22b outputs 1 when the test rest (remaining number) is zero, and generation of the first data WD2 is ended.

The OR circuit 22a generates the interruption signal when the error flag ERF is 1 or the output of the AND circuit 22b is 1.

The flip-flops 23 and 24 are provided so as to cause the end flag ENF and the bit position information to be delayed and conform to a timing of writing. The flip-flops 23 and 24 may be D-type flip-flops.

The selector 20e selects the read data RD1 read by the CPU 11 when the test enabling signal TE is 0, and selects the test data (result of the test) TD when the test enabling signal TE is 1. The test data TD is obtained by summarizing the test rest, the bit position, the end flag ENF, the error flag ERF, and the like. The selector 20e also serves as an output circuit which outputs the test data TD.

It is desired that the number of bits of the test data TD is equal to the number of bits of the data RD1 or RD2 which is read from the semiconductor memory. The test data TD is represented by TD[N:0]=Test Rest[X:0]+Bit Pos[Y:0]+ENF+ERF] which is obtained by summarization, when the read data RD1 is represented by RD1[N:0].

When the first data WD2 includes one hot data (WD2a) and satisfies N=31, Y=4. X indicates the number of bits determined by using the test size (total number).

The selector 20e outputs the selected information (RD1 or TD) to the CPU 11 via the bus 14.

An address of a word including a defective bit is expressed as test starting address+test size (total number)−test rest (remaining number), and may be calculated by the CPU 11.

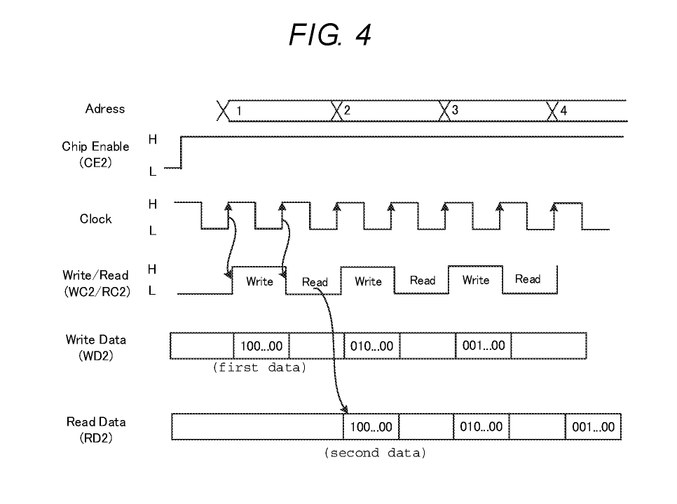

Next, a writing and reading operation by the semiconductor error detection apparatus 13 will be described. FIG. 4 is a timing chart illustrating an operation of writing the first data WD2 and reading the second data RD2.

As illustrated in FIG. 4, the writing and reading operation is performed when the chip enabling signal CE2 is High.

When a write/read signal (write command WC2) is High at a rising edge of a first clock signal, the first data WD2 is written in the memory cell unit designated by the address AD2.

When the write/read signal (read command RC2) is Low at a rising edge of a second clock signal, the second data RD2 is read from the memory cell unit designated by the address AD2. The read second data RD2 is output at the next writing cycle.

For example, when the first data WD2 are (100 . . . 00), an expected values of the second data RD2 are (100 . . . 00) which are the same as the first data WD2.

That is, the write command WC2 and the read command RC2 (enabling signals of writing and reading) are alternately output. Data is written at a first cycle of the clock and data is read at a second cycle. One bit may be tested for a period of time of two cycles of the clock signal.

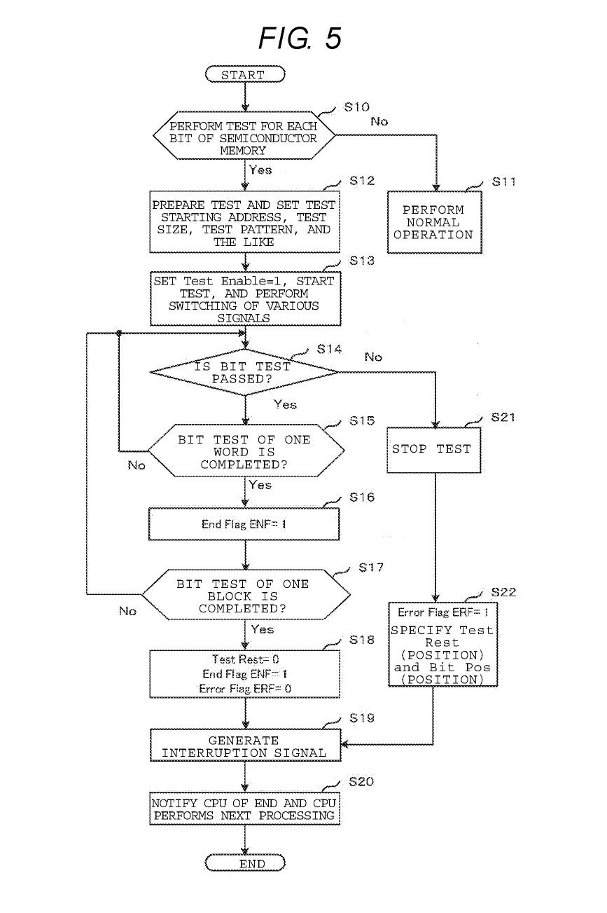

Next, an operation of the semiconductor error detection apparatus 13 will be described. FIG. 5 is a flowchart illustrating procedures of the test for each bit.

As illustrated in FIG. 5, first, it is determined whether or not the test for each bit for the semiconductor memory 12 is performed (Step S10). When the test for each bit is not performed (No in Step S10), the semiconductor integrated apparatus 10 performs the normal operation (Step S11). The semiconductor error detection apparatus 13 does not operate.

When the test for each bit is performed (Yes in Step S10), test preparation is carried out. The test starting address, the test size (total number), the test pattern, and the like are set during the test preparation (Step S12).

Then, the test enabling signal TE becomes 1, and the various signals described above are switched by the selection circuit 20 (Step S13).

Then, the test for each bit is performed in accordance with the timing chart illustrated in FIG. 4 (Step S14). When one bit passed the test (Yes in Step S14), it is determined whether or not performing of the test for each bit of one word is completed (Step S15).

When the test for each bit of one word is not completed (No in Step S15), the process returns to Step S14. Processes of Steps S14 and S15 are repeated until the test for each bit is performed on every bit of the one word.

When the test for each bit of one word is completed (Yes in Step S15), the end flag ENF is set (Step S16).

Then, it is determined whether or not the test for each bit of one block (corresponding to the test size (total number)) is completed (Step S17). When the test for each bit of one block is not completed (No in Step S17), the process returns to Step S14. Processes of Steps S14 to S16 are repeated until the test for each bit of the one block is completed.

When the test for each bit of one block is completed (Yes in Step S17), the test rest (remaining number) becomes 0, the end flag ENF is set as 1 (Step S18), and an interruption for the CPU 11 occurs (Step S19).

Then, the CPU 11 is notified of passing of the test for each bit of one block in the semiconductor memory 12 by the interruption. The CPU 11 may start the following processing (Step S20).

When the one bit did not pass the test (No in Step S14), the test for each bit is stopped (Step S21). An address of a memory cell unit including the defective bit and a position of the defective bit are specified using the test rest (remaining number), and the error flag ERF is set (Step S22). Then, the process proceeds to Step S19. The CPU 11 is notified of occurrence of the error in the semiconductor memory 12 by the interruption signal.

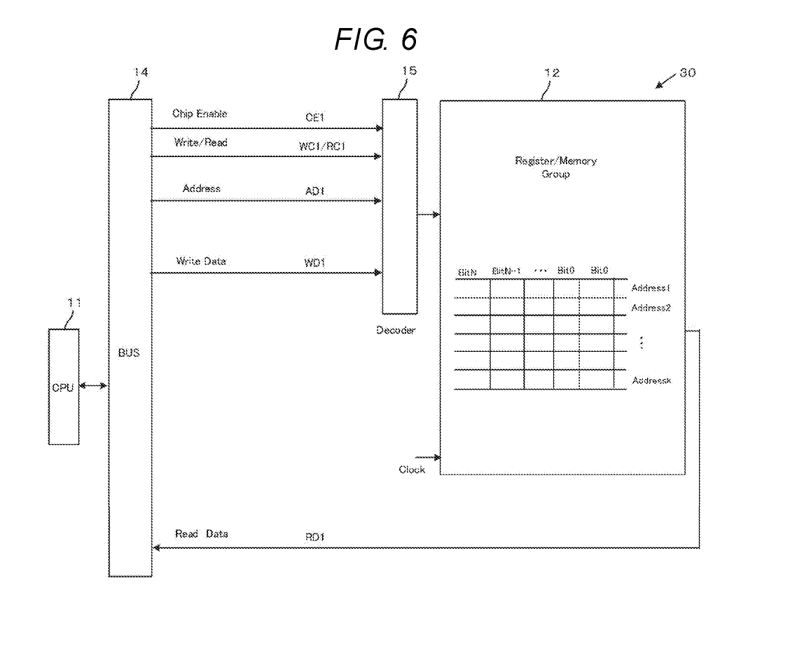

FIG. 6 illustrates a semiconductor integrated apparatus of a comparative example. The semiconductor integrated apparatus according to the comparative example does not include the semiconductor error detection apparatus 13 illustrated in FIG. 2.

As illustrated in FIG. 6, in the semiconductor integrated apparatus 30 according to the comparative example, when the test for each bit is performed, the CPU 11 transmits an address, a write command, and write data (first data) via the bus 14, and the first data are written in the semiconductor memory 12. The CPU 11 transmits an address and a read command, and second data are read from the semiconductor memory 12. Then, the first data and the second data are compared to each other.

For this reason, a period of time longer than two cycles of the clock signal is necessary to carry out the test for one bit. Thus, a period of time necessary to carry out the test for each bit would be much longer. Further, since the CPU 11 may not perform other processing while performing of the test, an initial operation time of the semiconductor integrated apparatus 30 would be longer.

In contrast, in the semiconductor integrated apparatus 10 according to the first embodiment, the semiconductor error detection apparatus 13 may performs the test for one bit during two cycles of the clock signal. As a result, it is possible to perform the test for each bit in a shorter period of time. Further, since the CPU 11 may perform other processing during the test, an initial operation of the semiconductor integrated apparatus 10 can be completed within a shorter initial operation time.

As described above, the semiconductor error detection apparatus 13 according to the first embodiment includes the address generation circuit 16, the data generation circuit 17, the control signal generation circuit 18, the comparison circuit 19, the selection circuit 20, and the test enabling circuit 21. The semiconductor error detection apparatus 13 according to the first embodiment performs the test for each bit of the semiconductor memory 12 with only hardware configuration.

The semiconductor error detection apparatus 13 writes data at the first cycle of the clock signal and reads data at the second cycle thereof, and then compares the written data with the read data at a third cycle thereof, at which data is written for the next test bit.

As a result, it is possible to perform the test for one bit during two cycles of the clock signal. Consequently, the semiconductor error detection apparatus according to the present embodiment can perform the test for each bit in a shorter period of time.

In the above embodiment, the clock signal of the semiconductor error detection apparatus 13 is the system clock signal of the semiconductor integrated apparatus 10. However, it is not particularly limited thereto. The clock signal of the semiconductor error detection apparatus 13 may be any clock signal that can be responded by the semiconductor error detection apparatus 13 and the semiconductor memory 12. For example, a clock signal faster than the system clock signal may be used. In this case, the test for each bit can be performed in further shorter period of time.

In the above embodiment, the test for each bit is performed in unit of one word (32 bits), but the unit of the test for each bit is not particularly limited. The test for each bit may be performed in unit of a half word (16 bits) or two words (64 bits).

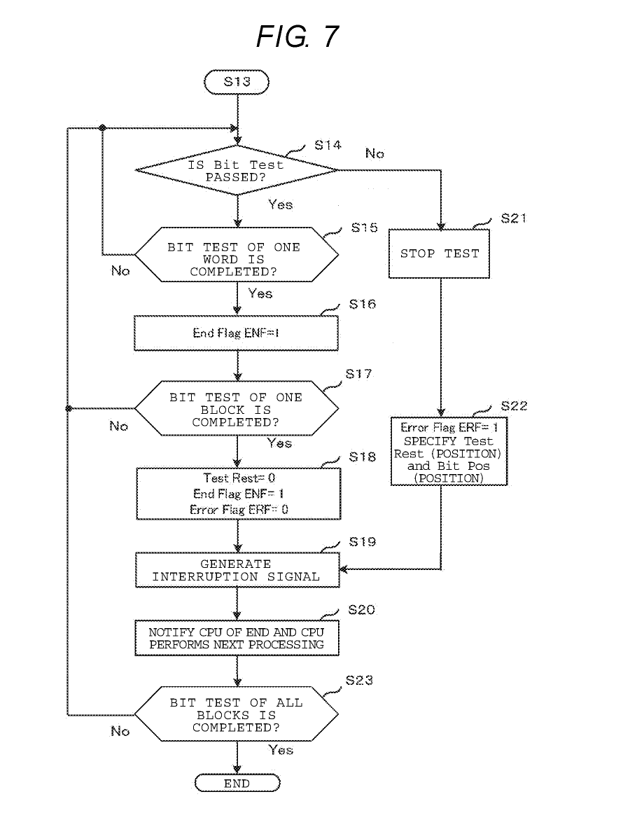

In the above embodiment, the bit test is performed on one block. When the test is performed on a plurality of blocks, processes of Steps S14 to S20 may be performed for each block. FIG. 7 is a flowchart illustrating a case where the bit test is performed on a plurality of blocks.

As illustrated in FIG. 7, when the test for each bit of one block is completed, it is determined whether or not the test on all blocks is completed (Step S21). When the test on all blocks is not completed (No in Step S21), the process returns to S14 and the processes of Steps S14 to S20 are repeated until the test on all blocks is completed.

### Second Embodiment

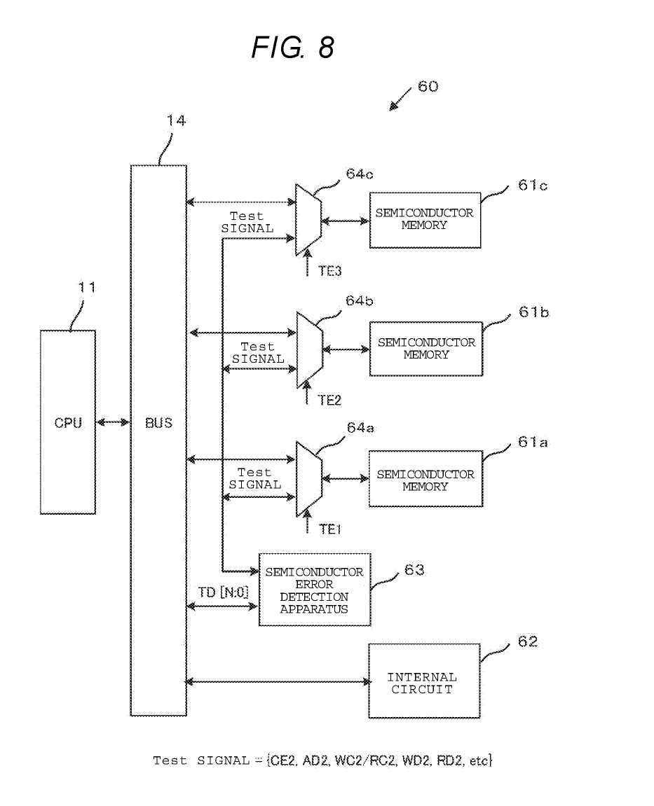

A semiconductor error detection apparatus according to a second embodiment will be described with reference to FIG. 8. FIG. 8 is a block diagram of a semiconductor integrated apparatus including the semiconductor error detection apparatus according to the second embodiment.

In the second embodiment, components same as those in the first embodiment are denoted by the same reference signs. Descriptions thereof will be omitted, and components different from those in the first embodiment will be mainly described. The second embodiment is different from the first embodiment in that the semiconductor integrated apparatus includes a plurality of semiconductor memories and the semiconductor error detection apparatus performs the test for each bit on each of the semiconductor memories.

That is, as illustrated in FIG. 8, the semiconductor integrated apparatus 60 according to the second embodiment includes the CPU 11 and the plurality of semiconductor memories (here, three semiconductor memories 61a, 61b, and 61c). The semiconductor integrated apparatus 60 may include an internal circuit 62 other than the semiconductor memories. The semiconductor integrated apparatus 60 further includes the semiconductor error detection apparatus 63 and selectors 64a, 64b, and 64c.

The selector 64a is provided so as to select connection of the semiconductor memory 61a the CPU 11 through the bus 14 or connection to the semiconductor error detection apparatus 63. A test enabling signal TE1 causes switching of the selector 64a.

The selector 64a causes the semiconductor memory 61a to be connected to the CPU 11 through the bus 14 when the test enabling signal TE1 is 0. The CPU 11 may perform writing and reading of data on the semiconductor memory 61a through the bus 14.

The selector 64a causes the semiconductor memory 61a to be connected to the semiconductor error detection apparatus 63 when the test enabling signal TE1 is 1. The semiconductor error detection apparatus 63 may perform the test for each bit of the semiconductor memory 61a.

The semiconductor error detection apparatus 63 is a semiconductor error detection apparatus that does not include the selectors 20a to 20e in the semiconductor error detection apparatus 13 illustrated in FIG. 2. The selector 64a is in charge of functions same as the selectors 20a to 20e.

The semiconductor error detection apparatus 63 receives various information on a test control, the test starting address, the test size (total number), and the like which are stored in a register of the semiconductor memory 61a, when the test for each bit starts to be performed on the semiconductor memory 61a.

The semiconductor error detection apparatus 63 transmits the chip enabling signal CE2, the address AD2, the read command RC2, the write command WC2, and the first data WD2 to the semiconductor memory 61a through the selector 64a, and receives the second data RD2 from the semiconductor memory 61a through the selector 64a.

A relationship of the selector 64b and the semiconductor memory 61b, and a relationship of the selector 64c and the semiconductor memory 61c are similar to the relationship of the selector 64a and the semiconductor memory 61a, and thus descriptions of the relationships will be omitted.

When an operation is started, the CPU 11 sets the test enabling signal TE1=1 and TE2=TE3=0. Thus, the semiconductor error detection apparatus 63 performs the test for each bit of the semiconductor memory 61a.

When each bit of the semiconductor memory 61a passed the test, the CPU 11 sets the test enabling signal TE2=1 and TE1=TE3=0. Then, the semiconductor error detection apparatus 63 performs the test for each bit of the semiconductor memory 61b. Similarly, when each bit of the semiconductor memory 61b passed the test, the CPU 11 sets the test enabling signal TE3=1 and TE1=TE2=0. Then, the semiconductor error detection apparatus 63 performs the test for each bit of the semiconductor memory 61c.

Accordingly, in one semiconductor error detection apparatus 63, the test for each bit may be sequentially performed on the plurality of semiconductor memories 61a, 61b, and 61c included in the semiconductor integrated apparatus 60. The number of semiconductor memories on which the test for each bit is performed is not particularly limited. Selectors of the number equal to the number of semiconductor memories may be provided.

The CPU 11 may access all of the semiconductor memories other than a semiconductor memory in the process of the test for each bit. Thus, it is possible to rapidly perform other processing.

As described above, the semiconductor error detection apparatus 63 according to the second embodiment may sequentially perform the test for each bit of the plurality of semiconductor memories 61a to 61c using a plurality of selectors 64a to 64c which is externally arranged.

The semiconductor integrated apparatus 60 may include one semiconductor error detection apparatus 63. Thus, the number of semiconductor error detection apparatuses does not need to be increased even if the number of the semiconductor memories is increased.

### Third Embodiment

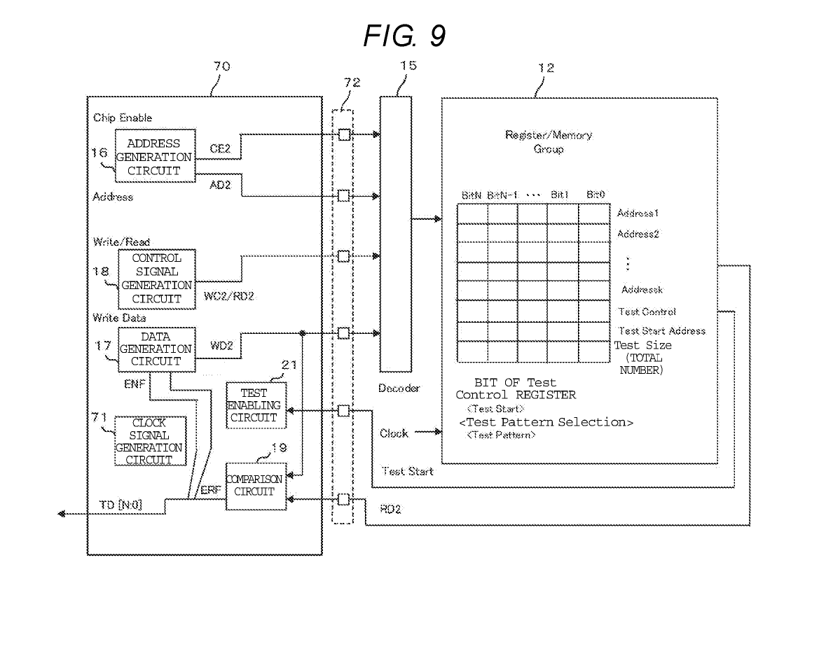

A semiconductor error detection apparatus according to the third embodiment will be described with reference to FIG. 9. FIG. 9 is a block diagram of the semiconductor error detection apparatus according to the third embodiment.

In the third embodiment, components same as those in the first embodiment are denoted by the same reference signs. Descriptions thereof will be omitted, and components different from those in the first embodiment will be described. The third embodiment is different from the first embodiment in that the semiconductor error detection apparatus is connected to the semiconductor memory independently from the connection between the CPU 11 and the semiconductor memory, and independently performs the test for each bit.

That is, as illustrated in FIG. 9, the semiconductor error detection apparatus 70 according to the third embodiment has the same configuration and functions as those in the semiconductor error detection apparatus 13 illustrated in FIG. 1 except that a selector for selecting connection to carry out the test for each bit is not included and a clock signal generation circuit 71 is included.

The semiconductor memory 12 is connected to the semiconductor error detection apparatus 70 through a connector 72 in a detachable manner, for example. The semiconductor error detection apparatus 70 performs, in synchronization with a clock signal from the clock signal generation circuit 71, performs the test for each bit of the semiconductor memory 12.

When each bit of the semiconductor memory 12 passed the test, the semiconductor memory 12 is detached from the semiconductor error detection apparatus 70. When another semiconductor memory is connected to the semiconductor error detection apparatus 70 through the connector 72, the semiconductor error detection apparatus 70 may perform the test for each bit of the newly connected semiconductor memory.

As described above, the semiconductor error detection apparatus 70 according to the third embodiment performs the test for each bit of the semiconductor memory 12 connected to the semiconductor error detection apparatus 70. The semiconductor error detection apparatus 70 may be used for a shipment inspection for the single packaged semiconductor memory, and the like.

Configurations as described in the following appendices may be considered.

### APPENDIX 1

A semiconductor integrated apparatus including: an information processing apparatus; a semiconductor memory; and a semiconductor error detection apparatus. Data is read and written from and in the semiconductor memory by the information processing apparatus. The semiconductor error detection apparatus is provided between the information processing apparatus and the semiconductor memory and performs a test for each bit of determining whether there are error parts in the semiconductor memory. The semiconductor error detection apparatus includes an address generation circuit, a data generation circuit, a control signal generation circuit, a comparison circuit, and a selection circuit. The address generation circuit generates an address for designating a memory cell in the semiconductor memory, which includes a test bit and a predetermined number of bits. The data generation circuit generates first data which includes test data to be written as the test bit, and is to be written in the memory cell designated by the address. The control signal generation circuit is used for an instruction of writing the first data in the memory cell designated by the address at a first cycle of a clock, and for an instruction of reading second data from the memory cell designated by the address at a second cycle of the clock. The comparison circuit compares the first data and the second data to each other and outputs a result of comparison. The selection circuit selects whether or not the test for each bit is performed.

### APPENDIX 2

The semiconductor integrated apparatus according to Appendix 1, in which the selection circuit causes the address generation circuit, the data generation circuit, and the control signal generation circuit to be electrically connected to the semiconductor memory when the test for each bit is performed, and causes the information processing apparatus to be electrically connected to the semiconductor memory when the test for each bit is not performed.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

What is claimed is:

1. An error detection apparatus, comprising:
an address generation circuit configured to output an address designating a memory cell unit of a semiconductor memory device to be tested, the memory cell unit including a plurality of memory bits;
a test data generation circuit configured to generate test data to be written to the memory cell unit;
a control circuit configured to cause the test data to be written to the memory cell unit designated by the address, in synchronization with a cycle of a clock signal, and the written test data to be read from the memory cell unit, in synchronization with the next cycle of the clock signal; and
a comparison circuit configured to compare the written test data and the read test data.

2. The error detection apparatus according to claim 1, further comprising:
a selection circuit configured to select connection of the semiconductor memory unit to the address generation circuit, the test data generation circuit, and the control circuit, or a memory controller.

3. The error detection apparatus according to claim 1, wherein
the address generation circuit is further configured to receive the number of memory bits to be tested, and periodically output one of different addresses corresponding to one of the memory bits to be tested.

4. The error detection apparatus according to claim 3, wherein
the test data generation circuit is configured to generate a group of test data, each test data having values for testing different one of the memory bits of the memory cell unit.

5. The error detection apparatus according to claim 4, wherein
the test data generation circuit is further configured to set an end flag when all of the test data in the group has been generated.

6. The error detection apparatus according to claim 1, wherein
the test data include a first value, which is a test value, and a second value that is different from the first value.

7. The error detection apparatus according to claim 1, further comprising:
a notification circuit configured to output a signal indicating whether or not at least one memory bit is defective.

8. The error detection apparatus according to claim 1, further comprising:
an output circuit configured to output data specifying a location of a defective memory bit.

9. The error detection apparatus according to claim 1, further comprising:
a clock signal generation circuit configured to generate the clock signal.

10. The error detection apparatus according to claim 1, further comprising:
a connector by which the semiconductor memory unit is attached and detached.

11. A memory system, comprising:
a semiconductor memory device including a plurality of memory cell units, each including a plurality of memory bits;
a memory controller configured to carryout write and read operations with respect to the semiconductor memory device; and
an error detection circuit configured to detect an error of a memory bit, the error detection circuit including:
an address generation circuit configured to output an address designating a memory cell unit of the semiconductor memory unit;
a test data generation circuit configured to generate test data to be written to the memory cell unit;
a control circuit configured to cause the test data to be written to the memory cell unit designated by the address, in synchronization with a cycle of a clock signal, and the written test data to be read from the memory cell unit, in synchronization with the next cycle of the clock signal; and
a comparison circuit configured to compare the written test data and the read test data.

12. The memory system according to claim 11, wherein
the error detection circuit further includes a selection circuit configured to select connection of the semiconductor memory unit to either the address generation circuit, the test data generation circuit, and the control circuit, or the memory controller.

13. The memory system according to claim 11, wherein
the address generation circuit is further configured to receive the number of memory bits to be tested, periodically output one of different addresses corresponding one of the memory bits to be tested.

14. The memory system according to claim 13, wherein
the data generation circuit is configured to generate a group of test data, each test data having values for testing different one of the memory bits of the memory cell unit.

15. The memory system according to claim 14, wherein
the test data generation circuit is further configured to set an end flag when all of the test data in the group has been generated.

16. The memory system according to claim 11, wherein
the test data include a first value, which is a test value, and a second value that is different from the first value.

17. The memory system according to claim 11, wherein
the error detection circuit further includes a notification circuit configured to output, to the memory controller, a signal indicating whether or not at least one memory bit is defective.

18. The memory system according to claim 11, wherein
the error detection circuit further includes an output circuit configured to output, to the memory controller, data specifying a location of a defective memory bit.

19. A method for testing a semiconductor memory device of a memory system, comprising:
attaching an error detection apparatus to the memory system;
outputting, from the error detection apparatus to the semiconductor memory device, an address designating a memory cell unit thereof, which includes a plurality of memory bits;
generating, at the error detection apparatus, test data to be written to the memory cell unit;
writing the generated test data to the memory cell unit designated by the address, in synchronization with a cycle of a clock signal;
reading the written test data from the memory cell unit, in synchronization with the next cycle of the clock signal; and
comparing the written test data and the read test data.
